(19) United States
(12) Patent Application Publication
(10) Pub. No.: US 2005/0093172 A1
(43) Pub. Date: May 5, 2005

(54) Electronic circuit device, and method and apparatus for manufacturing the same

(76) Inventors: Norihito Tsukahara, Kyoto (JP); Kazuhiro Nishikawa, Osaka (JP); Kazuto Nishida, Osaka (JP)

Correspondence Address: MCDERMOTT WILL & EMERY LLP, 600 13TH STREET, N.W., WASHINGTON, DC, 20005-3096, US

(21) Appl. No.: 10/959,324

(22) Filed: Oct. 7, 2004

(30) Foreign Application Priority Data
Oct. 10, 2003 (JP) 2003-352019

(51) Int. Cl. H01L 21/48; H01L 23/52

(52) U.S. Cl. 257/778; 438/108; 257/780; 438/614; 257/676; 438/123

(57) ABSTRACT

An electronic circuit device has a substrate having a wiring pattern, an electronic component electrically connected to a terminal section of the wiring pattern by contacting a projection electrode with it, a cover that is disposed at a position facing the substrate and grapples the electronic component between it and the substrate, and a resin layer made of thermoplastic resin filled in a gap between the substrate and the cover. The gap includes a space in a connection region except an electric connection part between the projection electrode and the terminal section. The electronic component is adhered to the substrate and the substrate is adhered to the cover through the resin layer. Thus, the electronic circuit device having high connection reliability and high mass productivity, and a method and apparatus for manufacturing the electronic circuit device can be provided.

### BACKGROUND OF THE INVENTION

1. Field of the Invention

The present invention relates to an electronic circuit device requiring thinness, such as an integrated circuit (IC) card, an IC-Tag, or a memory card, and a method and apparatus for manufacturing the electronic circuit device.

2. Background Art

Recently, performance of mobile devices such as portable phones has been increased, and IC cards and memory cards used in them have been thinned and capacity thereof have been increased. Additionally, non-contact IC-Tags attract attention for automatically recognizing article prices or the like.

An IC card, for example, is formed to be thin by inserting a semiconductor integrated circuit element (hereinafter called IC) into an opening of a substrate and adhering a flat-plate-like cover onto the substrate. Japanese Patent Unexamined Publication No. H11-175682 discloses the following IC card and a method of manufacturing it.

FIG. 11 is a sectional view of an essential part of this IC card, and FIG. 12 is a sectional view showing an intermediate process of the manufacturing method. The manufacturing method of the IC card is described with reference to FIG. 12. Firstly, bare chip type IC 3 having projection electrodes 311 is mounted to a predetermined position of substrate 2 having a predetermined wiring pattern 1 on its surface. This mounting method includes a method in which an isotropic conductive film is used as joining member 122, or a method in which projection electrodes 311 and wiring pattern 1 are interconnected through a conductive adhesive such as silver paste, and adhered and fixed to each other with joining member 122 composed of an insulating adhesive.

Next, spacer 4 having opening 411 in a part corresponding to a mounting part of IC 3 in a sheet made of thermoplastic resin, namely a hot melt adhesive, is stacked on substrate 2. Flat-plate-like cover 5 having thermoplastic resin layer 511 made of the same kind of resin as the thermoplastic resin of spacer 4 on its one surface is stacked on spacer 4 so that thermoplastic resin layer 511 faces spacer 4.

Then, substrate 2 and cover 5 are heated and pressed, thereby thermally press-bonding substrate 2 and spacer 4 together and spacer 4 and thermoplastic resin layer 511 together.

The thermoplastic resin of spacer 4 and thermoplastic resin layer 511 of cover 5 are thus unified to form unified resin layer 6 shown in FIG. 11. Substrate 2, cover 5, and IC 3 are bonded together by one thermoplastic resin layer between substrate 2 and cover 5, thereby forming IC card 7.

In the manufacturing method of the IC card discussed above, the joining member such as the isotropic conductive film or silver paste used for electrically connecting the projection electrodes of the IC to the wiring pattern is hard and less flexible. When the IC card is bent in a manufacturing process or during handling, a crack sometimes occurs in the joining member to cause a conduction failure. The spacer requires an opening, and the spacer must be positioned with high precision and adhered.

The present invention provides an electronic circuit device having high connection reliability between a terminal section of the wiring pattern and an electronic component and high mass productivity, and provides a method and apparatus for manufacturing the electronic circuit device.

### SUMMARY OF THE INVENTION

An electronic circuit device of the present invention has the following elements:
a substrate having a wiring pattern;
an electronic component electrically connected to a terminal section of the wiring pattern by contacting a projection electrode with it;
a cover that is disposed at a position facing the substrate and grapples the electronic component between it and the substrate; and
a resin layer made of thermoplastic resin and filled in a gap between the substrate and the cover, which includes a space in a connection region except an electric connection part between the projection electrode and the terminal section.
   The electronic component is adhered to the substrate and the substrate is adhered to the cover through the resin layer.

A manufacturing method of the electronic circuit device of the present invention has the following steps of:
forming a resin layer made of thermoplastic resin on a surface of a substrate having a wiring pattern;
positioning an electronic component having a projection electrode to a terminal section of the wiring pattern and temporarily fixing the electronic component to the resin layer;
disposing a cover on the temporarily fixed electronic component, pressing the electronic component via the cover while heating and softening the resin layer, removing the resin layer between the terminal section of the wiring pattern and the projection electrode by flowing, and contacting and electrically connecting the terminal section with the projection electrode; and
cooling the resin layer, adhering and fixing the electronic component to the substrate, adhering and fixing the substrate to the cover, and keeping the electric connection between the projection electrode and the terminal section.

A manufacturing apparatus of the electronic circuit device of the present invention has the following elements:
a resin layer forming means for forming a resin layer made of thermoplastic resin on a surface of a substrate having a wiring pattern;
a means for positioning an electronic component having a projection electrode to a terminal section of the wiring pattern and temporarily fixing the electronic component to the resin layer;
a pressing means for disposing a cover on the temporarily fixed electronic component, pressing the electronic component via the cover while heating and softening the thermoplastic resin, removing the resin layer between the terminal section of the wiring pattern and the projection electrode by flowing, and contacting and electrically connecting the terminal section with the projection electrode; and
an adhering and fixing means for cooling the resin layer, adhering and fixing the electronic component to the substrate, adhering and fixing the substrate to the cover, and keeping the electric connection between the projection electrode and the terminal section.

Since the electronic component is adhered to the substrate and the cover through a single thermoplastic resin layer in this structure, even when an external force such as a folding force is exerted to the electronic circuit device, the connection between the projection electrode of the electronic component and the terminal section of the wiring pattern is kept strong and conductive reliability can be improved. The structure as the electronic circuit device is simple, so that the manufacturing process can be simplified and the manufacturing yield can be also improved.

### BRIEF DESCRIPTION OF THE DRAWINGS

FIG. 1 is a sectional view of an essential part of a non-contact IC-Tag as an electronic circuit device in accordance with a first exemplary embodiment of the present invention.

FIG. 2 is a plan view of the upper surface of a substrate of the IC-Tag in accordance with the first exemplary embodiment.

FIG. 3 is a sectional view of an essential part of an IC-Tag as a deformed example in accordance with the first exemplary embodiment.

FIG. 4A is a sectional view of an essential part showing an electric connection structure where the tip of a projection electrode bites into a terminal section and presses and deforms the terminal section in the IC-Tag in accordance with the first exemplary embodiment.

FIG. 4B is a sectional view of an essential part showing an electric connection structure where the tip of the projection electrode breaks through the terminal section and arrives at the substrate surface in the IC-Tag in accordance with the first exemplary embodiment.

FIG. 4C is a sectional view of an essential part showing an electric connection structure where the tip of the projection electrode deforms to simultaneously press and deform the terminal section, namely both the tip and the terminal section deform, in the IC-Tag in accordance with the first exemplary embodiment.

FIG. 5 is a sectional view of an essential part of an electronic circuit device as another deformed example in accordance with the first exemplary embodiment.

FIG. 6A is a schematic diagram showing an adhering step of a thermoplastic resin layer in a manufacturing process of the electronic circuit device in accordance with the first exemplary embodiment.

FIG. 6B is a schematic diagram showing a temporarily fixing step of an IC in the manufacturing process of the electronic circuit device in accordance with the first exemplary embodiment.

FIG. 6C is a schematic diagram showing a step of electrically connecting the projection electrode of the IC to the terminal section by heating the thermoplastic resin layer to flow in the manufacturing process of the electronic circuit device in accordance with the first exemplary embodiment.

FIG. 6D is a schematic diagram showing a step of adhering and fixing the resin layer by solidification in the manufacturing process of the electronic circuit device in accordance with the first exemplary embodiment.

FIG. 7 is a schematic diagram showing a deformation example of an apparatus and method for manufacturing the electronic circuit device in accordance with the first exemplary embodiment.

FIG. 8A is a sectional view of an essential part showing a step of installing a reinforcing plate between an IC and a cover sheet in a manufacturing method of the deformed example of the electronic circuit device in accordance with the first exemplary embodiment.

FIG. 8B is a sectional view of an essential part showing a step of adhering and fixing the resin layer by solidification in the manufacturing method of the deformed example of the electronic circuit device in accordance with the first exemplary embodiment.

FIG. 9 is a sectional view of an essential part of an electronic circuit device in accordance with a second exemplary embodiment of the present invention.

FIG. 10 is a sectional view of an essential part of an electronic circuit device as a deformed example in accordance with the second exemplary embodiment.

FIG. 11 is a sectional view of an essential part of a conventional IC card.

FIG. 12 is a sectional view of an intermediate process illustrating a manufacturing method of the conventional IC card.

### DETAILED DESCRIPTION OF THE INVENTION

Non-contact IC-Tags as electronic circuit devices in accordance with exemplary embodiments of the present invention are described with reference to the drawings. The IC-Tags have a built-in coil for an antenna and IC, and perform communication with an external apparatus via the coil for the antenna.

First Exemplary Enbodiment

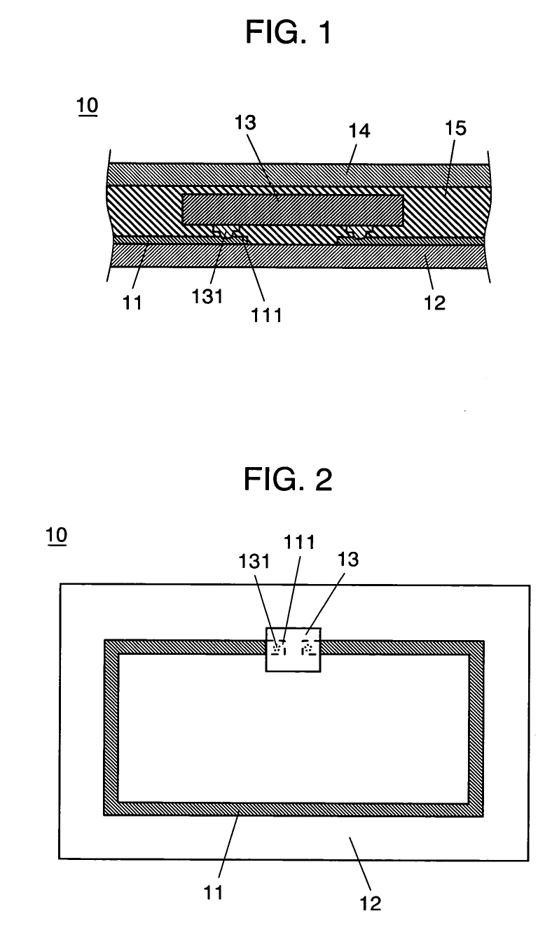

FIG. 1 is a sectional view of an essential part of IC-Tag 10 as an electronic circuit device in accordance with a first exemplary embodiment of the present invention. FIG. 2 is a plan view of the upper surface of IC-Tag 10. In FIG. 2, a cover and a resin layer are not drawn for sake of simplicity.

As shown in FIG. 2, IC-Tag 10 of the first exemplary embodiment has longitudinal length of several millimeters, lateral length of several millimeters, and thickness of some hundreds of micrometers. Substrate 12 has wiring patterns 11 including a coil for an antenna on its surface. IC 13 having projection electrodes 131 is mounted to terminal sections 111 of wiring patterns 11 of substrate 12. IC 13 has a bare chip structure, and is about 0.5 mm to 0.7 mm square. The number of projection electrodes 131 is three, and one of them is used as a dummy. Projection electrodes 131 of IC 13 are electrically connected to terminal sections 111 of wiring patterns 11.

IC 13 is sandwiched between substrate 12 and flat-plate-like cover 14 facing substrate 12, and all of them are adhered and fixed through resin layer 15 made of thermoplastic resin. The periphery of IC 13 except electric connection parts between projection electrodes 131 and terminal sections 111 is provided with resin layer 15, and IC 13 is tightly adhered and fixed to substrate 12 and cover 14 through resin layer 15.

Since the whole periphery of IC 13 is surrounded by resin layer 15 made of the same thermoplastic resin and adhered and fixed to substrate 12 and cover 14, IC-Tag 10 of the present embodiment has high adhesion stability. As a result, the connection between projection electrodes 131 of IC 13 and terminal sections 111 of wiring patterns 11 is kept tight, and also connection failure hardly occurs even when an external force such as a folding force is exerted to IC-Tag 10. In other words, even when the external force such as the folding force is exerted to the electronic circuit device, an electronic component is adhered to the substrate and cover through a single thermoplastic resin layer. The connection between the projection electrodes of the electronic component and the terminal sections of the wiring pattern is kept tight, and conductive reliability can be improved. The number of used members is small, the structure is simple, and the electronic component is adhered and fixed to the substrate and cover, so that connection failure hardly occurs even when temperature of a using environment of IC-Tag 10 varies and reliability as the electronic circuit device can be improved. The structure of the electronic circuit device is simple as discussed below, so that the manufacturing process can be simplified and the manufacturing yield can be also improved.

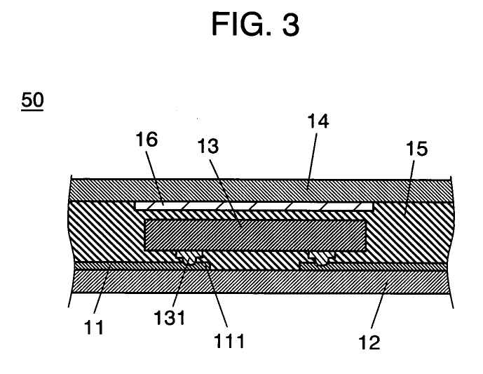

FIG. 3 is a sectional view of an essential part of a deformed example IC-Tag 50 in accordance with the first exemplary embodiment. In IC-Tag 50, also, IC 13 has a bare chip structure. In this deformed example, reinforcing plate 16 having a shape similar to that of IC 13 is disposed above IC 13 facing cover 14. Reinforcing plate 16 may be made of material such as metal, high-strength plastics, or high-toughness ceramics having folding strength larger than that of a semiconductor substrate forming IC 13. Here, the metal includes stainless steel or copper, and the semiconductor substrate includes a silicon single crystal substrate or a gallium arsenide single crystal substrate. The thickness of reinforcing plate 16 depends on modulus of elasticity of the employed material, but is preferably about 50 to 100 μm. Reinforcing plate 16 may be larger than IC 13 or smaller than IC 13. When reinforcing plate 16 is smaller than IC 13, reinforcing plate 16 is positioned as close to the central part of IC 13 as possible, and preferably has a size for covering at least a half the area of IC 13.

Disposing reinforcing plate 16 allows prevention of breakage of IC 13 or the electric connection part even when a folding force or a pressing force is exerted to IC-Tag 50. By adhering and fixing reinforcing plate 16 to cover 14 or IC 13, positional displacement from IC 13 can be prevented.

In other words, the electronic circuit device in the deformed example further has the reinforcing plate between the cover and the surface of the electronic component facing the cover. This reinforcing plate may be adhered or fixed to the cover, the electronic component, or both of them.

In this structure, the reinforcing plate can suppress an external force during folding or pressing the electronic circuit device from affecting not only the electronic component body but also the electric connection parts between the projecting electrodes and the wiring patterns. As a result, the reliability of the electronic circuit device can be improved.

Main construction materials of IC-Tags 10 and 50 as the electronic circuit devices of the present embodiment are described hereinafter.

Substrate 12 is preferably formed, in a sheet shape, of polyethylene terephthalate (PET), polyethylene naphthalate, polyimide, or glass epoxy resin, but is not limited to this. Wiring pattern 11 is formed on substrate 12. The material of wiring patterns 11 is preferably aluminum, but is not limited to this. For example, a single metal film made of copper, gold, or silver, an alloy film of them, or a printing conductor film of silver paste conductor or the like can be employed. The terminals of wiring patterns 11 define terminal sections 111 for connection.

Resin layer 15 is made of resin having thermo plasticity and adhesiveness, such as polyester, ethylene vinyl alcohol, or styrene-butadiene elastomer.

Cover 14 is preferably made of insulating material such as PET or polyethylene naphthalate, but may be a metal plate such as a thin stainless steel plate. When the metal plate is used for cover 14, parts of substrate 12 on which wiring patterns 11 constituting an antenna are formed are required to have no conductor layer.

For substrate 12 and cover 14, material of which heat-resistant temperature is higher than a softening temperature of resin layer 15 must be employed.

As IC 13, a bare chip having projection electrodes 131 such as stud bumps or plating bumps is often employed, but a chip size package (CSP) or the like having projection electrodes 131 on one surface may be employed.

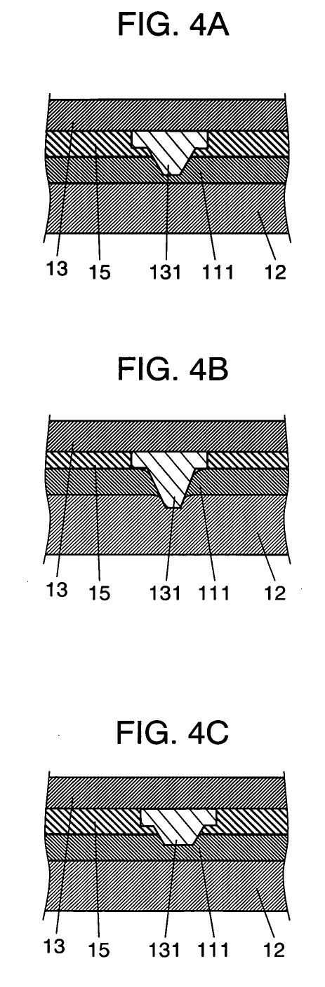

Connection structure between terminal sections 111 of wiring patterns 11 on substrate 12 and projection electrodes 131 of IC 13 is described hereinafter. FIG. 4A to FIG. 4C are enlarged sectional views of three kinds of electric connection parts. In FIG. 4A, the tips of the projection electrodes 131 bite into terminal sections 111 to press and deform terminal sections 111, thereby establishing the electric connection. In FIG. 4B, the tips of projection electrodes 131 break through terminal sections 111 and arrive at the surface of substrate 12, thereby establishing the electric connection. In FIG. 4C, the tips of projection electrodes 131 deform and simultaneously press and deform terminal sections 111, thus both the tips and terminal sections 111 are deformed and electrically interconnected. As known from FIG. 4A to FIG. 4C, electric connection parts have a curve structure where at least one of projection electrode 131 and terminal section 111 deforms and curves around the other. The curve structure of the electric connection parts allows projection electrodes 131 to contact with terminal sections 111 of wiring patterns 11 on a large surface. Additionally, not only vertical contact pressure but also diagonal contact pressure is applied to the surface of substrate 12, so that stable electric connection can be kept.

IC-Tags 10 and 50 as the electronic circuit devices of the present embodiment have the structure discussed above. Information from an external apparatus is received as radio by wiring patterns 11 including a coil for an antenna and processed by IC 13, thereby performing data communications with the external apparatus.

This structure allows realization of the electronic circuit devices having a function of transmitting or receiving information from the external apparatus by radio via an antenna. For example, a non-contact IC card or IC-Tag for transmitting or receiving data recorded in the IC using radio power via an antenna can be realized.

The above description takes IC-Tags 10 and 50 as an example. In each of them, wiring patterns 11 formed on substrate 12 correspond to the coil for an antenna, and the electronic component corresponds to the bare-chip-type IC 13. However, the present invention is not limited to the IC-Tags. The present invention is instantly estimated to be applied to an IC card, but the present invention can be also applied to an electronic circuit device where a plurality of ICs provide a function of transmitting or receiving information in a non-contact manner.

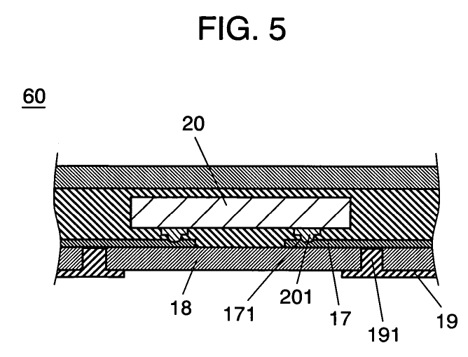

FIG. 5 is a sectional view of an essential part of electronic circuit device 60 as another deformed example in accordance with the first exemplary embodiment. Wiring patterns 17 are formed on substrate 18. External connection terminals 19 to be connected to an external apparatus (not shown) are formed on the opposite surface to the surface of substrate 18 to which electronic component 20 is adhered. External connection terminals 19 are connected to wiring patterns 17 through conducting section 191 formed of a penetrating conductive pattern. As electronic component 20, not only a bare-chip-type IC but also a package-type IC such as a chip size package (CSP) can be employed. Projection electrodes 201 are formed on electronic component 20, and electronic component 20 is connected to terminal sections 171 of wiring patterns 17 through projection electrodes 201. The number of electronic components 20 is not limited to one, but may be two or more.

Thanks to this structure, electronic circuit device 60 can transmit or receive information from the external apparatus via external connection terminals 19. Electronic circuit device 60 transmits or receives information in a contact manner, so that power supply to electronic component 20 can be easy and further complicated electronic circuit device 60 can be realized.

In other words, an electronic circuit device for communicating information to an external apparatus in a contact manner via an external connection terminal, for example a memory card, can be easily realized.

In the present embodiment, various electronic circuit devices can be provided as discussed above. The electronic circuit devices include, for example, a simple electronic circuit device using only one bare-chip-type or package-type IC having a projection electrode, and a complicated electronic circuit device using a plurality of ICs including a memory element.

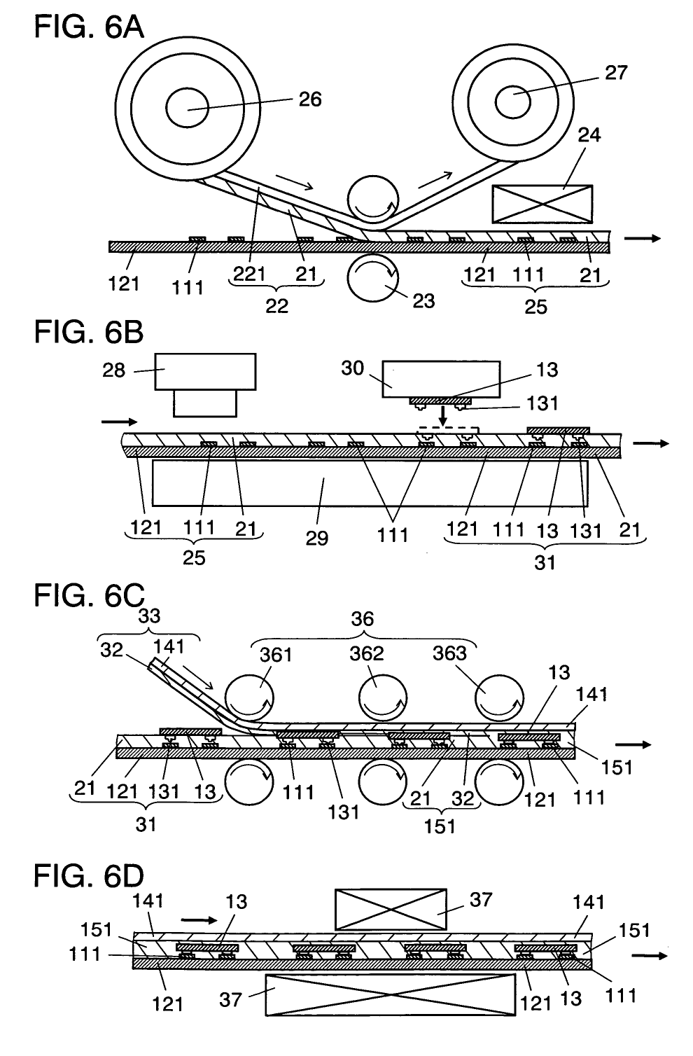

A method and apparatus for manufacturing the electronic circuit device of the present embodiment are hereinafter described using a manufacturing case of IC-Tag 10 as an example. FIG. 6A to FIG. 6D are schematic diagrams showing a manufacturing apparatus and a manufacturing process of the electronic circuit device in accordance with the first exemplary embodiment.

In the manufacturing apparatus and manufacturing method, at least cover 14 is made of flexible material, substrate 12, thermoplastic resin layer 21, and cover 14 are supplied to the manufacturing apparatus in a continuous long sheet state, and many IC-Tags 10 are produced continuously by process. The manufacturing apparatus and manufacturing method of the present invention are not limited to this. For example, the manufacturing apparatus and manufacturing method where an electronic circuit device is manufactured using a certain-shaped substrate and a cover in a batch method with a pressing jig, a heating jig, and a cooling jig.

In process A by the manufacturing apparatus, as shown in FIG. 6A, film-like thermoplastic resin layer 21 is adhered to substrate sheet 121 that has wiring patterns and their terminal sections 111 at a predetermined interval. Film-like thermoplastic resin layer 21 is adhered to sheet 221 for conveyance to form resin sheet 22. Resin sheet 22 and substrate sheet 121 are disposed so that a surface of thermoplastic resin layer 21 faces wiring patterns 11, passed between a pair of heating/pressurizing rollers 23, and cooled by cooling unit 24, thereby forming substrate sheet 25 having a resin layer. Resin sheet 22 is supplied from reel 26, and sheet 221 for conveyance is wound up by reel 27.

In process B, as shown in FIG. 6B, thermoplastic resin layer 21 of substrate sheet 25 is preheated by heating machine 28, and is moved by conveying table 29 having a heater while being heated. Projection electrodes 131 of IC 13 are positioned to terminal sections 111 of wiring patterns 11 by mounting machine 30, and IC 13 is temporarily fixed onto thermoplastic resin layer 21, thereby forming substrate sheet 31 having a chip.

IC 13 can obtain sufficient adhesive strength by burying projection electrodes 131 into thermoplastic resin layer 21 or by burying projection electrodes 131 and part of IC 13 body into thermoplastic resin layer 21, so that IC 13 can be temporarily fixed in a stable state hardly causing displacement. The temporary fixing may be performed by pressing IC 13 to bury projection electrodes 131 at normal temperatures especially without heating thermoplastic resin layer 21.

In process C, as shown in FIG. 6C, resin sheet 33 for a cover formed by adhering sheet-like thermoplastic resin layer 32 to sheet 141 for a cover is used. Resin sheet 33 and substrate sheet 31 are passed between a pair of pressurizing rollers 36 while the surface of thermoplastic resin layer 32 is overlapped on IC 13 of substrate sheet 31 having the chip. During the passing, thermoplastic resin layers 21 and 32 are heated and softened, and IC 13 is pressed via resin sheet 33. In this operation, thermoplastic resin layer 21 between projection electrodes 131 and terminal sections 111 is made to flow and is removed, and projection electrodes 131 contact with terminal sections 111 as shown in FIG. 4 to provide electric connection. Thermoplastic resin layer 32 of resin sheet 33 for the cover and thermoplastic resin layer 21 of resin sheet 22 are made of the same material, so that the layers are unified to form resin layer 151 during the pressing.

IC 13 is adhered to both substrate sheet 121 and sheet 141 for the cover through resin layer 151 while projection electrodes 131 and terminal sections 111 are electrically interconnected, thereby producing IC-Tag 10.

The pair of pressurizing rollers 36 are formed of a plurality of sets of rollers (three sets of rollers in the present embodiment) 361, 362 and 363 having different pressing force or roller interval. Rollers 361, 362 and 363 are arranged so that pressing force sequentially increases or roller interval sequentially decreases. When substrate sheet 31 having the chip and resin sheet 33 for the cover that grapple IC 13 are made to pass sequentially between the plurality of sets of rollers 361, 362 and 363, the pressing force is exerted gradually. Therefore, displacement of IC 13 hardly occurs during pressing, and flowing of thermoplastic resin layers 21 and 32 is smoothened. As a result, projection electrodes 131 of IC 13 and terminal sections 111 of wiring patterns 11 can be connected certainly. Pressurizing rollers 36 may have a structure also capable of performing heating. Especially when rollers 361 and 362 additionally have a heating mechanism, resin layer 151 can be simultaneously heated and pressurized by rollers 361 and 362. This is efficient.

In the method discussed above, the connection between the terminal sections of the wiring patterns and the projection electrodes of the IC and adhesion of the substrate to the cover can be performed only by previously temporarily fixing the electronic component, disposing the cover, and pressing them. Therefore, the mass and continuous production of the electronic circuit devices is allowed, and the cost of the electronic circuit devices can be reduced.

In the pressing process, the electronic component is pressed by a predetermined dimension via the cover, and the projection electrodes of the electronic component are contacted with the terminal sections of the wiring patterns to provide electric connection. This pressing process can be performed rapidly and with high mass productivity. The pressing means is formed of a plurality of sets of rollers having different pressing force or roller interval, so that displacement of the electronic component hardly occurs during the pressing, and mass productivity can be improved.

In the structure of the electronic circuit devices, the projection electrodes of the electronic component are electrically connected to the terminal sections of the wiring patterns, the electronic component is adhered to the substrate, and the substrate is adhered to the cover through thermoplastic resin. Thanks to this structure, a manufacturing apparatus for manufacturing a large number of electronic circuit devices at high mass productivity can be realized.

In process D, as shown in FIG. 6D, resin layer 151 is cooled by cooling unit 37 and solidified in a state where projection electrodes 131 of IC 13 are electrically connected to terminal sections 111. The work in a continuous sheet state is completed at this time. Cooling in the pressed state is sometimes preferable dependently on the material of the thermoplastic resin layer, but in a case using this material, a plurality of rollers are arranged up to the proximity of cooling unit 37 shown in FIG. 6D and pressurization is performed.

The temperatures of heating/pressurizing rollers 23 and pressurizing rollers 36 are set lower than heat resistant temperatures of materials used for substrate sheet 121 and sheet 141 for the cover and higher than softening temperatures of thermoplastic resin layers 21 and 32. Temperatures of respective rollers 361, 362 and 363 of pressurizing rollers 36 may be varied in response to a manufacturing condition.

Then, in a state where a plurality of IC-Tags 10 are formed, characteristic inspection is performed if necessary and IC-Tags 10 are then cut, thereby providing separated IC-Tags 10. The characteristic inspection may be performed in a separated state.

IC-Tag 10 that has been determined to be defective can be easily replaced by a non-defective IC by heating resin layer 15 and removing cover 14.

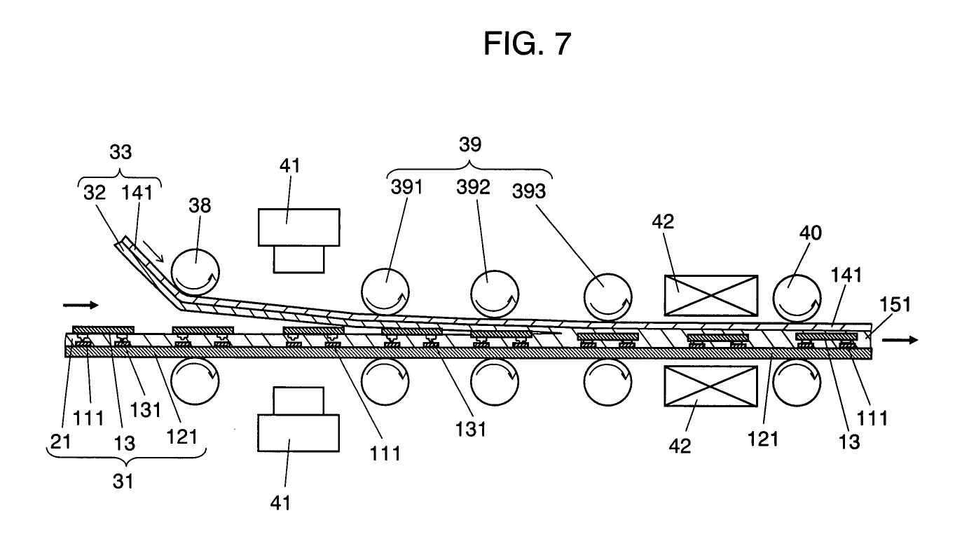

In the method and apparatus for manufacturing the electronic circuit device of the present embodiment, the electric connection process of projection electrodes 131 of IC 13 to terminal sections 111 by pressing and the solidifying process of resin layer 151 are performed independently. However, the present invention is not limited to this. For example, an apparatus structure shown in FIG. 7 may be employed. FIG. 7 shows a manufacturing apparatus and manufacturing method where adhesion of resin sheet 33 for the cover to substrate sheet 31 having the chip, electric connection between projection electrodes 131 of IC 13 and terminal sections 111, and adhesion and fixing by solidifying resin layer 151 can be continuously performed. A pair of rollers 38 are disposed on the inlet side of the substrate sheet 31 and resin sheet 33, and a pair of rollers 40 are similarly disposed on the outlet side thereof Heating units 41, pressurizing rollers 39, and cooling units 42 are disposed between rollers 38 and 40. Pressurizing rollers 39 are formed of three sets of rollers 391, 392 and 393 in the apparatus shown in FIG. 7. Pressurizing rollers 39 are arranged so that pressing force sequentially increases or roller interval sequentially decreases, similarly to the rollers discussed above.

Thanks to this structure, the adhesion of resin sheet 33 onto substrate sheet 31, the electric connection between projection electrodes 131 of IC 13 and terminal sections 111, and the adhesion and fixing by solidifying resin layer 151 can be continuously performed. As a result, productivity of the electronic circuit devices can be greatly improved. In this structure, cooling can be performed just after the pressurizing state, so that degree of selection freedom of thermoplastic resin can be increased.

The manufacturing apparatus may employ not only the structure where the above processes are continuously performed but also a continuous production structure including the above processes, the adhering process of thermoplastic resin layers 21 onto substrate sheet 121, and the mounting process of IC 13.

In these structures, the pressing means and the adhering and fixing means are continuously formed through the rollers. Adhering and fixing can thus performed before the electric connection part between projection electrodes and the terminal sections interconnected in the pressing process varies, so that the manufacturing apparatus of the electronic circuit devices having high connection reliability can be realized. Since the heating means is disposed on the inlet side of the plurality of sets of rollers and the cooling means is disposed on the outlet side, the manufacturing apparatus of the electronic circuit devices having continuity and high mass productivity can be realized.

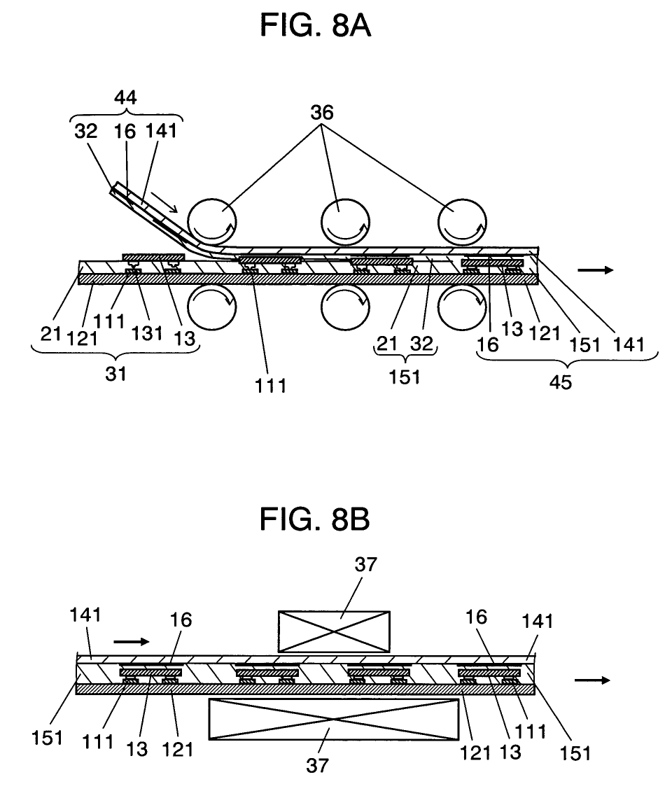

When IC-Tag 50 as an electronic circuit device having reinforcing plate 16 shown in FIG. 3 is manufactured, a method shown in FIG. 8A and FIG. 8B is employed. FIG. 8A and FIG. 8B are sectional views of essential parts showing a manufacturing process of disposing reinforcing plate 16 between IC 13 and sheet 141 for the cover. In FIG. 8A, similarly to process C of the manufacturing method, resin sheet 44 for the cover is adhered to substrate sheet 31 having the chip and they are passed between pressurizing rollers 36, thereby electrically connecting projection electrodes 131 of IC 13 to terminal sections 111 and solidifying resin layer 151 to perform adhering and fixing. At this time, employed resin sheet 44 has reinforcing plate 16 held at a position on sheet 141 corresponding to IC 13 and has thermoplastic resin layer 32 on sheet 141 including reinforcing plate 16.

In FIG. 8B, adhering and fixing are performed in a process similar to process D. Resin layer 151 is cooled by cooling unit 37 in a state where projection electrodes 131 of IC 13 is connected to terminal sections 111, IC 13 is adhered and fixed to substrate sheet 121, substrate sheet 121 is adhered and fixed to sheet 141, and IC 13 is adhered and fixed to reinforcing plate 16. IC-Tags 50 protected by reinforcing plate 16 are continuously formed on substrate sheet 121.

Since the reinforcing plate is adhered onto the electronic component and the electronic component is adhered and fixed to both the substrate and the cover through the resin layer, the electronic circuit devices having high reliability can be manufactured.

Then, in a state where a plurality of IC-Tags 50 are formed, characteristic inspection is performed if necessary and IC-Tags 10 are then cut, thereby providing separated IC-Tags 50. The characteristic inspection may be performed in a separated state.

In the method and apparatus for manufacturing the electronic circuit device of the present embodiment, the periphery of the electronic component is adhered and fixed to the substrate and the cover through the resin layer made of the same thermoplastic resin, so that reliability of the adhesion is improved. When the electronic component is temporarily fixed to the terminal section, also, the adhesion is effectively used to allow certain fixing. Displacement or the like hardly occurs in the pressing process, and the manufacturing yield is also improved.

In the method and apparatus for manufacturing the electronic circuit device of the present embodiment, for forming a thermoplastic resin layer on a substrate sheet, a method of adhering a thermoplastic resin layer formed on a sheet for conveyance to the substrate sheet is used; however the present invention is not limited to this. The thermoplastic resin layer may be formed on the substrate sheet by coating or printing, and may be thinner than the electronic component. The thickness may be set more than an enough value to allow temporary fixing and set so that the sum of the thickness of this thermoplastic resin layer and the thickness of a thermoplastic resin layer formed on the sheet for the cover is substantially equal to or slightly more than that of the electronic component.

In the method and apparatus for manufacturing the electronic circuit device of the present embodiment, the electronic component is temporarily fixed by softening the thermoplastic resin with the heating unit or the conveying table having the heater; however the electronic component may be temporarily fixed at normal temperatures.

In the method and apparatus for manufacturing the electronic circuit device of the present embodiment, the resin layer made of thermoplastic resin is solidified by the cooling unit; however, the present invention is not limited to this. The resin layer may be cooled by being pressed by a cooled roller.

Second Exemplary Enbodiment

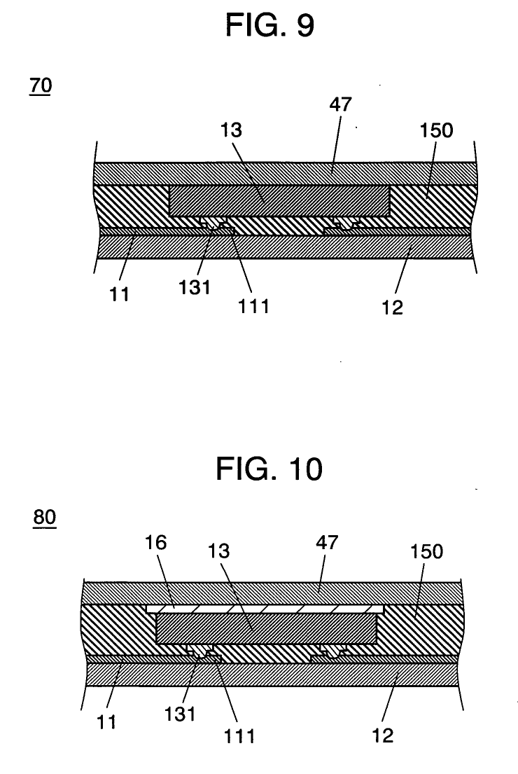

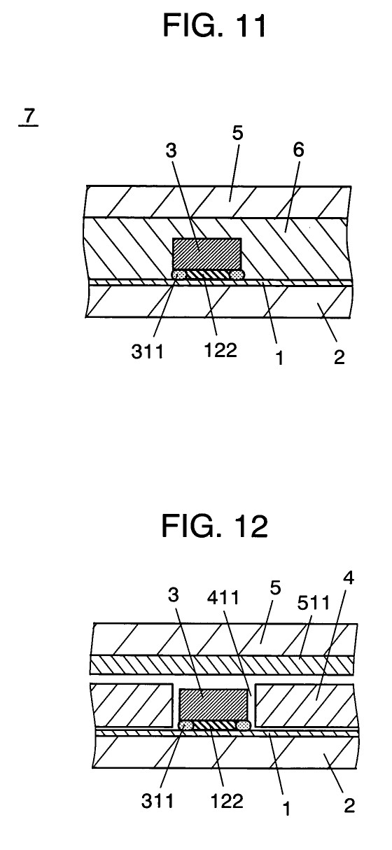

FIG. 9 is a sectional view of an essential part of an electronic circuit device in accordance with a second exemplary embodiment of the present invention. IC-Tag 70 is described as an example of the electronic circuit device in the present embodiment, so that the same elements as those in FIG. 1 to FIG. 8B are denoted with the same reference numbers. In FIG. 9, IC-Tag 70 of the present embodiment has the same basic structure as that of IC-Tag 10 of the first embodiment. In other words, IC 13 having projection electrodes 131 is mounted to a predetermined position of substrate 12 having predetermined wiring patterns 11 as a coil for an antenna on its surface, and projection electrodes 131 are electrically connected to terminal sections 111 of wiring patterns 11. IC 13 is sandwiched between substrate 12 and flat-plate-like cover 47 facing substrate 12 to be adhered and fixed, similarly to IC-Tag 10 of the first embodiment. In the present embodiment, however, resin layer 150 made of thermoplastic resin is not disposed between IC 13 and cover 47. Resin layer 150 is filled in a region other than a clearance between IC 13 and cover 47 to adhere and fix IC 13, cover 47, and substrate 12, but cover 47 tightly contacts with IC 13 differently from the first embodiment.

This structure allows further decrease. of thickness of the electronic circuit device. Even when the electronic circuit device is folded or even when dimension variation difference between the electronic component and the cover is generated by temperature variation, breakage can be prevented by sliding between the electronic component and the cover.

Since IC 13 tightly contacts with cover 47 in IC-Tag 70 of the present embodiment, thickness of IC-Tag 70 can be further decreased and failure of electric connection hardly occurs even when folding is performed or temperature varies.

FIG. 10 is a sectional view of an essential part of IC-Tag 80 as a deformed example in accordance with the second exemplary embodiment. In IC-Tag 80 as the deformed example, reinforcing plate 16 is disposed above IC 13 tightly contacting with cover 47. Reinforcing plate 16 can be made of the same material as that of the first embodiment, so that the description of reinforcing plate 16 is omitted. Even when a folding force or a pressing force of IC-Tag 80 is exerted, breakage of the IC or a failure of the electric connection part hardly occurs.

In other words, adhering and fixing the reinforcing plate to the cover or the electronic component allow a reinforcing effect to be further certainly obtained. Since the electronic component tightly contacts with the reinforcing plate, stress due to thermal expansion coefficient difference between the electronic component and the reinforcing plate does not act on the electronic component even when a metal plate having a large thermal expansion coefficient is used as the reinforcing plate. Therefore, the degree of selection freedom of the reinforcing plate increases.

IC-Tags 70 and 80 of the second embodiment may have the structure illustrated in the deformed example of the first embodiment in FIG. 5.

IC-Tags 70 and 80 of the second embodiment can manufactured by the manufacturing apparatus and the manufacturing method shown in the first embodiment. A sheet for a cover having no thermoplastic resin layer is overlapped on a substrate sheet having a chip differently from the first embodiment. In IC-Tags 70 and 80, the IC is pressed by heating and softening thermoplastic resin with the heating/pressurizing rollers while the reinforcing plate tightly contacts with the IC, so that displacement can be decreased. When the reinforcing plate is previously adhered to the cover in IC-Tag 80, the manufacturing can be facilitated.

IC-Tags having a bare-chip-type IC are described as electronic circuit devices in the first and second embodiments; however, the present invention is not limited to these. The present invention can be applied to a contact-type IC card or a non-contact-type IC card. The present invention can be also applied to an electronic circuit device such as a memory card having a function of communicating information to an external apparatus in a contact method or a non-contact method. The electronic circuit device may have not only a bare-chip structure but also a mold-type IC having projection electrodes on one surface, such as a chip-size-package (CSP), and a chip component as a receiving component. The electronic circuit device may have a plurality of ICs or chip components.

In the electronic circuit device of the present invention, the projection electrodes of the electronic component are electrically connected to the terminal sections of the wiring patterns, and the electronic component is adhered to the substrate and the substrate is adhered to the cover through thermoplastic resin. Therefore, even when an external force such as a folding force is exerted, connection reliability between the electronic component and the terminal sections of the wiring patterns is high, and mass productivity is high. The apparatus and method for manufacturing the electronic circuit device allow mass production at a low cost, and are useful in an electronic circuit device field where an IC card or an IC-Tag are required to be small, light, and thin.

1. An electronic circuit device comprising:
a substrate having a wiring pattern;
an electronic component electrically coupled to a terminal section of the wiring pattern by contacting a projection electrode with the terminal section of the wiring pattern;
a cover that is disposed at a position facing the substrate and grapples the electronic component between the cover and the substrate; and
a resin layer made of thermoplastic resin and filled in a gap between the substrate and the cover, the gap including a space in a coupling region except an electric coupling part between the projection electrode and the terminal section,
wherein the electronic component is adhered to the substrate and the substrate is adhered to the cover through the resin layer.

2. An electronic circuit device according to claim 1,
wherein a surface of the electronic component facing the cover is adhered and fixed to the cover through the resin layer.

3. An electronic circuit device according to claim 1,
wherein a surface of the electronic component facing the cover tightly contacts with the cover.

4. An electronic circuit device according to claim 1,
wherein a reinforcing plate is further disposed between the cover and a surface of the electronic component facing the cover.

5. An electronic circuit device according to claim 4,
wherein the reinforcing plate is adhered and fixed to the cover.

6. An electronic circuit device according to claim 4,
wherein the reinforcing plate is adhered and fixed to the electronic component.

7. An electronic circuit device according to claim 1,
wherein the electric coupling part between the projection electrode of the electronic component and the terminal section of the wiring pattern has a curve structure where at least one of the projection electrode and the terminal section deforms and curves around the other.

8. An electronic circuit device according to claim 7,
wherein the electric coupling part has a structure where a tip of the projection electrode penetrates the terminal section and arrives at a surface of the substrate.

9. An electronic circuit device according to claim 1, wherein
the electronic component is a semiconductor integrated circuit element of which one surface has the projection electrode, and
one or more electronic components are mounted on the substrate.

10. An electronic circuit device according to claim 9, wherein
the wiring pattern forming at least an antenna is formed on the substrate,
the terminal section of the wiring pattern is electrically coupled to the projection electrode of the semiconductor integrated circuit element, and
the electronic circuit device has a function of communicating information to an external apparatus in a non-contact manner.

11. An electronic circuit device according to claim 9, wherein
an external connection terminal for coupling to an external apparatus is formed on a surface of the substrate, the surface being opposite to a surface for receiving the electronic component,
the external connection terminal is electrically coupled to the wiring pattern,
the terminal section of the wiring pattern is electrically coupled to the projection electrode of the semiconductor integrated circuit element, and
the electronic circuit device has a function of communicating information to the external apparatus with the external connection terminal.

12. A manufacturing method of an electronic circuit device comprising:
forming a resin layer made of thermoplastic resin on a surface of a substrate having a wiring pattern;
positioning an electronic component having a projection electrode to a terminal section of the wiring pattern and temporarily fixing the electronic component to the resin layer;
disposing a cover on the temporarily fixed electronic component, pressing the electronic component via the cover while heating and softening the resin layer, removing the resin layer between the terminal section of the wiring pattern and the projection electrode by flowing, and contacting and electrically coupling the terminal section with the projection electrode; and
cooling the resin layer, adhering and fixing the electronic component to the substrate, adhering and fixing the substrate to the cover, and keeping the electrical coupling between the projection electrode and the terminal section.

13. A manufacturing method of an electronic circuit device according to claim 12, wherein
in the process of temporarily fixing the electronic component to the resin layer, the projection electrode is positioned to the terminal section, and the projection electrode or part of a body of the electronic component is then buried in the resin layer to temporarily fix the electronic component.

14. A manufacturing method of an electronic circuit device according to claim 12, wherein
in the process of temporarily fixing the electronic component to the resin layer, the resin layer is heated and softened, and then the projection electrode or part of a body of the electronic component is buried in the resin layer to temporarily fix the electronic component.

15. A manufacturing method of an electronic circuit device according to claim 12, wherein
a thermoplastic resin layer made of the same material as the thermoplastic resin is formed on a surface of the cover facing the electronic component,
in the process of pressing the electronic component to contact and electrically couple the terminal section with the projection electrode, the electronic component is pressed via the cover having the thermoplastic resin layer to electrically couple the terminal section with the projection electrode, and
in the process of cooling the resin layer to perform adhesion and fixing, the electronic component is adhered and fixed to both the substrate and the cover through the thermoplastic resins formed on the cover and the substrate.

16. A manufacturing method of an electronic circuit device according to claim 12, wherein
a reinforcing plate is disposed at a position facing the electronic component on the cover,
in the process of pressing the electronic component to contact and electrically couple the terminal section with the projection electrode, the electronic component is pressed via the cover having the reinforcing plate to electrically couple the terminal section with the projection electrode, and
in the process of cooling the resin layer to perform adhesion and fixing, the electronic component is adhered and fixed to the substrate and the cover while the electronic component tightly contacts with the reinforcing plate.

17. A manufacturing method of an electronic circuit device according to claim 12, wherein
a reinforcing plate is disposed at a position facing the electronic component on the cover,
a thermoplastic resin layer made of the same material as the thermoplastic resin is formed on a surface of the cover including the reinforcing plate,
in the process of pressing the electronic component to contact and electrically couple the terminal section with the projection electrode, the electronic component is pressed via the cover that has the reinforcing plate and the thermoplastic resin layer to electrically couple the terminal section with the projection electrode, and
in the process of cooling the resin layer to perform adhesion and fixing, the electronic component is adhered and fixed to the reinforcing plate and the substrate through the thermoplastic resins formed on the cover and the substrate.

18. A manufacturing method of an electronic circuit device according to claim 12, wherein
the cover is made of a material having flexibility, and
in the process of pressing the electronic component to contact and electrically couple the terminal section with the projection electrode, the substrate and the cover grappling the electronic component are pressed by being passed between rollers using pressing means having a pair of rollers faced on both sides.

19. A manufacturing method of an electronic circuit device according to claim 18, wherein
the pressing means has a plurality of pairs of rollers that have different pressing force and different roller interval and are faced to each other on both ends, the pressing force increases or the roller interval decreases in a passing order of the substrate and the cover grappling the electronic component between the plurality of pairs of rollers,
in the process of pressing the electronic component to contact and electrically couple the terminal section with the projection electrode, the substrate and the cover grappling the electronic component are pressed by being passed between the plurality of pairs of rollers.

20. A manufacturing apparatus of an electronic circuit device comprising:
resin layer forming means for forming a resin layer made of thermoplastic resin on a surface of a substrate having a wiring pattern;
means for positioning an electronic component having a projection electrode to a terminal section of the wiring pattern and temporarily fixing the electronic component to the resin layer;
pressing means for disposing a cover on the temporarily fixed electronic component, pressing the electronic component via the cover while heating and softening the resin layer, removing the thermoplastic resin between the terminal section of the wiring pattern and the projection electrode by flowing, and contacting and electrically coupling the terminal section with the projection electrode; and
adhering and fixing means for cooling the resin layer, adhering and fixing the electronic component to the substrate, adhering and fixing the substrate to the cover, and keeping the electrical coupling between the projection electrode and the terminal section.

21. A manufacturing apparatus of an electronic circuit device according to claim 20, wherein
the pressing means and the adhering and fixing means have a plurality of pairs of rollers faced to each other on both ends, and
the substrate and the cover grappling the electronic component are continuously pressed, adhered, fixed by being passed between the rollers.

22. A manufacturing apparatus of an electronic circuit device according to claim 21, wherein
the plurality of pairs of rollers have heating means on the inlet side of the substrate and the cover grappling the electronic component and have cooling means on the outlet side.
